(19) United States
(12) Patent Application Publication
(10) Pub. No.: US 2026/0105235 A1
(43) Pub. Date: Apr. 16, 2026

(54) METHOD, SEMICONDUCTOR CIRCUIT, AND SYSTEM WITH SEMICONDUCTOR CIRCUIT DESIGN

(71) Applicants: Samsung Electronics Co., Ltd., Suwon-si (KR); Seoul National University R&DB Foundation, Seoul (KR)

(72) Inventors: Jooyeon JEONG, Seoul (KR); Taewhan KIM, Seoul (KR)

(73) Assignees: Samsung Electronics Co., Ltd., Suwon-si (KR); Seoul National University R&DB Foundation, Seoul (KR)

(21) Appl. No.: 19/245,729

(22) Filed: Jun. 23, 2025

(30) Foreign Application Priority Data
Jun. 21, 2024 (KR) 10-2024-0080818
Sep. 27, 2024 (KR) 10-2024-0132137

(51) Int. Cl. G06F 30/392; G06F 30/3947; H03K 3/037; H10D 89/10

(52) U.S. Cl. CPC G06F 30/392; G06F 30/3947; H03K 3/0372; H10D 89/10

(57) ABSTRACT

A semiconductor circuit including a first flip-flop configured to extend along a first direction and a second flip-flop configured to extend parallel to the first flip-flop along the first direction, the first flip-flop including a first fixed length circuit including one of input/output pins of the first flip-flop and a first variable length circuit including another of the input/output pins of the first flip-flop, the second flip-flop including a second fixed length circuit including one of input/output pins of the second flip-flop and a second variable length circuit including the other of the input/output pins of the second flip-flop, and a second length of the second variable length circuit in the first direction is configured to be longer by a predetermined first length than a first length of the first variable length circuit in the first direction.

### CROSS-REFERENCE TO RELATED APPLICATION

This application claims priority to and the benefit under 35 U.S.C § 119(a) of Korean Patent Application No. 10-2024-0080818 filed in the Korean Intellectual Property Office on Jun. 21, 2024, and Korean Patent Application No. 10-2024-0132137 filed in the Korean Intellectual Property Office on Sep. 27, 2024, the entire disclosures of which are incorporated herein by reference for all purposes.

### BACKGROUND

### (a) Technical Field

The present disclosure relates to a semiconductor circuit, a semiconductor circuit design system, and a method for designing a semiconductor circuit.

### (b) Description of the Related Art

A flip-flop is a basic memory device used in digital circuits, and it may operate on the rising edge or falling edge of a clock signal to receive and store data or maintain its existing state. A multi-bit flip-flop is a device designed by integrating multiple single-bit flip-flops into a single cell, which reduces the area occupied in the circuit and reduces power consumption by utilizing shared resources such as clock buffers.

### SUMMARY

This Summary is provided to introduce a selection of concepts in a simplified form that are further described below in the Detailed Description. This Summary is not intended to identify key features or essential features of the claimed subject matter, nor is it intended to be used as an aid in determining the scope of the claimed subject matter.

In a general aspect, here is provided a semiconductor circuit including a first flip-flop configured to extend along a first direction and a second flip-flop configured to extend parallel to the first flip-flop along the first direction, the first flip-flop including a first fixed length circuit including one of input/output pins of the first flip-flop and a first variable length circuit including another of the input/output pins of the first flip-flop, the second flip-flop including a second fixed length circuit including one of input/output pins of the second flip-flop and a second variable length circuit including the other of the input/output pins of the second flip-flop, and a second length of the second variable length circuit in the first direction is configured to be longer by a predetermined first length than a first length of the first variable length circuit in the first direction.

A first side extending in a second direction perpendicular to the first direction may be defined by a cell boundary of a multi-bit flip-flop cell layout of the semiconductor circuit in the first variable length circuit is configured to be misaligned with a second side extending in the second direction which may be defined by the cell boundary in the second variable length circuit and the multi-bit flip-flop cell layout may include the first flip-flop and the second flip-flop.

The first side may be configured to form a straight line with the second side.

The second variable length circuit includes a first upsizing circuit pattern extending a width of a cell layout with respect to the first variable length circuit.

The first upsizing circuit pattern may be configured to have a second drive strength of the second flip-flop be “a” times of a first drive strength of the first flip-flop and “a” is a real number greater than 1.

The semiconductor circuit may include a clock generation circuit and the first flip-flop and the second flip-flop may be placed directly adjacent to each other while sharing the clock generation circuit.

The semiconductor circuit may include a third flip-flop configured to extend parallel to the first flip-flop and the second flip-flop along the first direction, the third flip-flop may include a third fixed length circuit including one of input/output pins of the third flip-flop and a third variable length circuit including the other of the input/output pins of the third flip-flop, and a third length of the third variable length circuit in the first direction may be configured to be longer by a predetermined second length than a first length of the first variable length circuit in the first direction.

A first side extending in a second direction perpendicular to the first direction may be defined by a cell boundary of a multi-bit flip-flop cell layout which may include the first flip-flop and the second flip-flop in the first variable length circuit, a second side extending in the second direction may be defined by the cell boundary in the second variable length circuit, and a third side extending in the second direction may be defined by the cell boundary in the third variable length circuit are configured to be misaligned with each other.

The third variable length circuit may include a second upsizing circuit pattern extending a width of a cell layout with respect to the first variable length circuit.

The second upsizing circuit pattern may be configured to have a third drive strength of the third flip-flop be “b” times a first drive strength of the first flip-flop and “b” may be a real number greater than a ratio “a”, the ratio “a” being a second drive strength of the second flip-flop to the first drive strength.

In a general aspect, here is provided a semiconductor circuit design system including one or more processors including processing circuitry, a memory including one or more storage media storing a layout design tool, the layout design tool being configured to design a layout of a semiconductor circuit and instructions that, when executed individually or collectively by the one or more processors, cause the semiconductor circuit design system to place a standard cell provided from a cell library according to a predetermined design rule, the standard cell including a multi-bit flip-flop cell layout, the multi-bit flip-flop cell layout including a first flip-flop formed to extend along a first direction and a second flip-flop formed to extend parallel to the first flip-flop along the first direction, the first flip-flop including a first fixed length circuit including one of input/output pins of the first flip-flop and a first variable length circuit including another of the input/output pins of the first flip-flop, the second flip-flop including a second fixed length circuit including one of input/output pins of the second flip-flop and a second variable length circuit including the other of the input/output pins of the second flip-flop, and a cell boundary of the multi-bit flip-flop cell layout includes a first side extending from the first fixed length circuit in a second direction perpendicular to the first direction, a second side extending from the second fixed length circuit in the second direction while forming a straight line with the first side, a third side extending from the first variable length circuit in the second direction, and a fourth side extending from the second variable length circuit in the second direction while being misaligned with the third side.

A second length of the second variable length circuit in the first direction may be formed to be longer than a first length of the first variable length circuit in the first direction by a predetermined first length.

The first flip-flop and the second flip-flop may be placed directly adjacent to each other while sharing a clock generation circuit.

The multi-bit flip-flop cell layout may further include a third flip-flop formed to extend parallel to the first flip-flop and the second flip-flop along the first direction, the third flip-flop may include a third fixed length circuit including one of input/output pins of the third flip-flop and a third variable length circuit including the other of the input/output pins of the third flip-flop, and a cell boundary of the multi-bit flip-flop cell layout may include a fifth side extending from the third fixed length circuit in the second direction while forming a straight line with the first side and the second side, and a sixth side extending from the third variable length circuit in the second direction while being misaligned with both the third side and the fourth side.

A third length of the third variable length circuit in the first direction may be formed to be longer than a first length of the first variable length circuit in the first direction by a predetermined second length.

In a general aspect, here is provided a processor-implemented method including executing a layout design tool for a layout design of a semiconductor circuit loaded into a memory device, accessing a cell library, selecting a standard cell provided from the cell library, placing the selected standard cell according to a predetermined design rule, and performing routing on the placed standard cell, the standard cell including a multi-bit flip-flop cell layout, the multi-bit flip-flop cell layout including a first flip-flop formed to extend along a first direction and a second flip-flop formed to extend parallel to the first flip-flop along the first direction, the first flip-flop including a first fixed length circuit including one of input/output pins of the first flip-flop and a first variable length circuit including another of the input/output pins of the first flip-flop, the second flip-flop including a second fixed length circuit including one of input/output pins of the second flip-flop and a second variable length circuit including the other of the input/output pins of the second flip-flop, and a cell boundary of the multi-bit flip-flop cell layout including a first side extending from the first fixed length circuit in a second direction perpendicular to the first direction, a second side extending from the second fixed length circuit in the second direction while forming a straight line with the first side, a third side extending from the first variable length circuit in the second direction, and a fourth side extending from the second variable length circuit in the second direction while being misaligned with the third side.

A second length of the second variable length circuit in the first direction may be formed to be longer than a first length of the first variable length circuit in the first direction by a predetermined first length.

The method may include placing the first flip-flop and the second flip-flop adjacent to each and the first flip-flop and the second flip-flop may share a clock generation circuit.

The multi-bit flip-flop cell layout further may include a third flip-flop configured to extend parallel to the first flip-flop and the second flip-flop along the first direction, and the third flip-flop may include a third fixed length circuit including one of input/output pins of the third flip-flop and a third variable length circuit including the other of the input/output pins of the third flip-flop, and a cell boundary of the multi-bit flip-flop cell layout may include a fifth side extending from the third fixed length circuit in the second direction while forming a straight line with the first side and the second side and a sixth side extending from the third variable length circuit in the second direction while being misaligned with both the third side and the fourth side.

A third length of the third variable length circuit in the first direction may be formed to be longer than a first length of the first variable length circuit in the first direction by a predetermined second length.

### BRIEF DESCRIPTION OF THE DRAWINGS

FIG. 1 illustrates an example semiconductor circuit according to one or more embodiments.

FIG. 2 illustrates an example semiconductor circuit according to one or more embodiments.

FIG. 3 illustrates an example semiconductor circuit according to one or more embodiments.

FIG. 4 illustrates an example semiconductor circuit according to one or more embodiments.

FIG. 5 illustrates an example semiconductor circuit according to one or more embodiments.

FIG. 6 illustrates an example semiconductor circuit according to one or more embodiments.

FIG. 7 illustrates example semiconductor circuits according to one or more embodiments.

FIG. 8 and FIG. 9 illustrate example electronic devices with timing violation resolution according to one or more embodiments.

FIG. 10 illustrates an example method for designing a semiconductor circuit according to one or more embodiments.

FIG. 11 illustrates an example electronic system according to one or more embodiments.

Throughout the drawings and the detailed description, unless otherwise described or provided, the same drawing reference numerals may be understood to refer to the same or like elements, features, and structures. The drawings may not be to scale, and the relative size, proportions, and depiction of elements in the drawings may be exaggerated for clarity, illustration, and convenience.

### DETAILED DESCRIPTION

The following detailed description is provided to assist the reader in gaining a comprehensive understanding of the methods, apparatuses, and/or systems described herein. However, various changes, modifications, and equivalents of the methods, apparatuses, and/or systems described herein will be apparent after an understanding of the disclosure of this application. For example, the sequences within and/or of operations described herein are merely examples, and are not limited to those set forth herein, but may be changed as will be apparent after an understanding of the disclosure of this application, except for sequences within and/or of operations necessarily occurring in a certain order. As another example, the sequences of and/or within operations may be performed in parallel, except for at least a portion of sequences of and/or within operations necessarily occurring in an order, e.g., a certain order. Also, descriptions of features that are known after an understanding of the disclosure of this application may be omitted for increased clarity and conciseness.

The features described herein may be embodied in different forms, and are not to be construed as being limited to the examples described herein. Rather, the examples described herein have been provided merely to illustrate some of the many possible ways of implementing the methods, apparatuses, and/or systems described herein that will be apparent after an understanding of the disclosure of this application. The use of the term “may” herein with respect to an example or embodiment (e.g., as to what an example or embodiment may include or implement) means that at least one example or embodiment exists where such a feature is included or implemented, while all examples are not limited thereto. The use of the terms “example”, “embodiment”, and “example embodiment” herein have a same meaning (e.g., the phrasing ‘in an or one example’ has a same meaning as ‘in an or one embodiment” and ‘in an or one example embodiment’), and “one or more examples” has a same meaning as “one or more embodiments” and “one or more example embodiments”. Still further, each of multiple or all separately described an/one “example”, “embodiment”, “example embodiment”, as well as “examples”, “embodiments”, “example embodiments”, herein may be included, in combination, in a same embodiment in any combination.

Although terms such as “first,” “second,” and “third”, or A, B, (a), (b), and the like may be used herein to describe various members, components, regions, layers, or sections, these members, components, regions, layers, or sections are not to be limited by these terms. Each of these terminologies is not used to define an essence, order, or sequence of corresponding members, components, regions, layers, or sections, for example, but used merely to distinguish the corresponding members, components, regions, layers, or sections from other members, components, regions, layers, or sections. Thus, a first member, component, region, layer, or section referred to in the examples described herein may also be referred to as a second member, component, region, layer, or section without departing from the teachings of the examples.

The terminology used herein is for describing various examples only and is not to be used to limit the disclosure. The articles “a,” “an,” and “the” are intended to include the plural forms as well, unless the context clearly indicates otherwise. As non-limiting examples, terms “comprise” or “comprises,” “include” or “includes,” and “have” or “has” specify the presence of stated features, numbers, operations, members, elements, and/or combinations thereof, but do not preclude the presence or addition of one or more other features, numbers, operations, members, elements, and/or combinations thereof, or the alternate presence of an alternative stated features, numbers, operations, members, elements, and/or combinations thereof. Additionally, while one embodiment may set forth such terms “comprise” or “comprises,” “include” or “includes,” and “have” or “has” specify the presence of stated features, numbers, operations, members, elements, and/or combinations thereof, other embodiments may exist where one or more of the stated features, numbers, operations, members, elements, and/or combinations thereof are not present.

Unless otherwise defined, all terms, including technical and scientific terms, used herein have the same meaning as commonly understood by one of ordinary skill in the art to which this disclosure pertains and specifically in the context on an understanding of the disclosure of the present application. Terms, such as those defined in commonly used dictionaries, are to be interpreted as having a meaning that is consistent with their meaning in the context of the relevant art and specifically in the context of the disclosure of the present application, and are not to be interpreted in an idealized or overly formal sense unless expressly so defined herein.

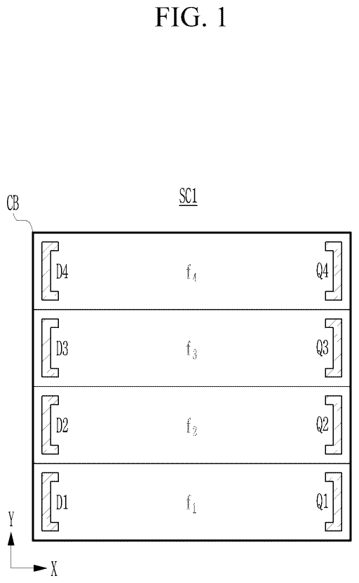

FIG. 1 illustrates an example semiconductor circuit according to one or more embodiments.

Referring to FIG. 1, in a non-limiting example, a semiconductor circuit may include a standard cell SC1 defining a multi-bit flip-flop.

The standard cell may be a predefined small circuit block used in the design of a semiconductor circuit. A standard cell may represent, for example, a digital circuit element such as a logic gate, a flip-flop, and a multiplexer, and may be designed to have a predetermined width and height. Designers may automate and optimize circuit design through consistent placement and routing using standard cells.

A multi-bit flip-flop may be designed by placing single-bit flip-flops in two or more rows. Basically, the drive strength of the single-bit flip-flops placed in respective rows may be designed to be the same. Drive strength refers to the strength of an output signal in a digital circuit and means how strongly a particular element may drive the signal. This may be mainly measured through the output current of the corresponding element.

In an example, the standard cell SC1 may have a plurality of flip-flops f₁, f₂, f₃, and f₄. Each of the plurality of flip-flops f₁, f₂, f₃, and f₄ may be, for form, a single bit flipflop. The flip-flop f₁ may include an input pin (or input terminal) D1 that receives data to be stored, and an output pin (or output terminal) Q1 that outputs the stored data. Although not shown, the flip-flop f₁ may additionally include a clock input pin or a clock buffer for receiving a clock signal for capturing data. The flip-flop f₁ may be placed at a row (hereinafter, referred to as a ‘first row’) defined at a lower end within the standard cell SC1 to extend along the first direction X.

In an example, the flip-flop f₂ may be placed at a row (hereinafter, referred to as a ‘second row’) defined above the first row within the standard cell SC1 to extend parallel to the flip-flop f₁ along the first direction X, and the flip-flop f₂ may include an input pin D2 and an output pin Q2. The flip-flop f₃ may be placed at a row (hereinafter, referred to as a ‘third row’) defined above the second row within the standard cell SC1 to extend parallel to the flip-flop f₁ and the flip-flop f₂ along the first direction X, and the flip-flop f₃ may include an input pin D3 and an output pin Q3. The flip-flop f₄ may be placed at a row (hereinafter, referred to as a ‘fourth row’) defined above the third row within the standard cell SC1 to extend parallel to the flip-flop f₁, the flip-flop f₂, and the flip-flop f₃ along the first direction X, and the flip-flop f₄ may include an input pin D4 and an output pin Q4. Here, the fourth row may be a row defined at an upper end within the standard cell SC1.

In an example, the flip-flop f₁ and the flip-flop f₂ may be placed directly adjacent to each other while sharing, among other things, a clock generation circuit. In addition, the flip-flop f₃ and the flip-flop f₄ may be placed directly adjacent to each other while also sharing, among other things, a clock generation circuit. That is, in an example, pairs of the flip-flops (i.e., flip-flops f1 and f₂ and flip-flops f3 and f₄) may share a clock generation circuit. In addition, example flip-flops and flip-flop pairs may share other circuits, inputs, outputs, etc.

Although the illustrated example of FIG. 1 may indicate that the standard cell SC1 is implemented as a 4-bit multi-bit flip-flop, this is only an example and the scope of the present disclosure is not limited thereto. The standard cell SC1 may be implemented as a k-bit multi-bit flip-flop for any positive integer k. In this case, k rows are defined within the standard cell SC1, and a single bit flip-flop may be placed in each row.

As illustrated, a cell boundary CB of the standard cell SC1 may be defined to include left sides extending in the second direction Y in the plurality of flip-flops f₁, f₂, f₃, and f₄, right sides extending in the second direction Y in the plurality of flip-flops f₁, f₂, f₃, and f₄, a lower side of the flip-flop f₁, and an upper side of the flip-flop f₄.

In some examples, in a multi-bit flip-flop, the drive strength of a single-bit flip-flop placed in each row may be designed to vary. For example, a method of increasing the drive strength of a standard cell may be used to increase the speed of a circuit or to enable the standard cell to drive a larger load. In this case, a method of increasing the width of a transistor configuring the standard cell may be used. Increasing the width of the transistor means expanding the active area of the transistor, which may actually mean increasing the width of the cell layout. For example, a standard cell (e.g., standard cell SC1) may have various drive strengths depending on which transistor's width is increased within the standard cell.

Particularly, in the case of a multi-bit flip-flop in the form of a multi-row cell configured of multiple single-bit flip-flops, there may be cases where the drive strength of only a specific single-bit flip-flop is desired to be increased. In this case, instead of a multi-bit flip-flop in which all single-bit flip-flops have the same drive strength, a method is needed to increase the drive strength of a specific single-bit flip-flop and consider only the width of the standard cell increased accordingly as the cell boundary.

Conventionally, when the width of a transistor is increased, the width of the standard cell also increases, and especially in the case of multi-row cells, even when the width of only some rows increases, the width of all rows is designed to increase equally. However, these typical methods add unnecessary empty space to the row that does not increase the width of the transistor within the cell laid out in a rectangular shape. An increase in such unnecessary empty space may lead to higher manufacturing costs, increased power consumption, and reduced chip density, which may impose significant constraints on semiconductor design.

Hereinafter, examples in which an unnecessary empty space is not formed for a case in which drive strength is variously designed in a multi-bit flip-flop will be described.

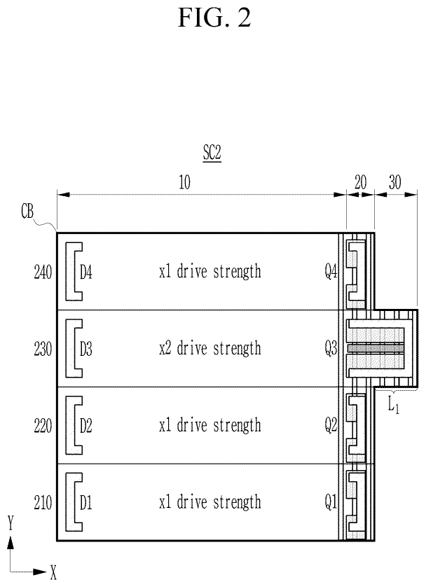

FIG. 2 illustrates an example semiconductor circuit according to one or more embodiments.

Referring to FIG. 2, in a non-limiting example, a semiconductor circuit may include a standard cell SC2 defining a multi-bit flip-flop. The standard cell SC2 may include a plurality of flip-flops 210, 220, 230, and 240.

The flip-flop 210 may be placed in the first row within the standard cell SC2 to extend along the first direction X, and the flip-flop 220 may be placed in the second row within the standard cell SC2 to extend parallel to the flip-flop 210 along the first direction X. The flip-flop 230 may be placed in the third row within the standard cell SC2 to extend parallel to the flip-flop 210 and the flip-flop 220 along the first direction X, and the flip-flop 240 may be placed in the fourth row within the standard cell SC2 to extend parallel to the flip-flop 210 to the flip-flop 230 along the first direction X.

In an example, the flip-flop 210 and the flip-flop 220 may be placed directly adjacent to each other while sharing, among other things, a clock generation circuit, as well as other circuits, devices, inputs, and outputs. In addition, the flip-flop 230 and the flip-flop 240 may be placed directly adjacent to each other while sharing the clock generation circuit, among other circuits, devices, inputs, and outputs.

The flip-flop 210 may include a first fixed length circuit and a first variable length circuit. Here, the first fixed-length circuit may be defined as a circuit area including a left side of an area occupied by the flip-flop 210 in the first row of the standard cell SC2 and including a point (a first middle point) that is a predetermined distance from the left side in the first direction X. Referring to FIG. 2, the first fixed length circuit may represent a circuit area corresponding to a range indicated by reference numeral 10 among the area occupied by the flip-flop 210 in the first row of the standard cell SC2. Meanwhile, the first variable length circuit may be defined as a circuit area including the right side among the area occupied by the flip-flop 210 in the first row of the standard cell SC2 and including the right side from the first middle point to the right side. The first variable length circuit may represent a circuit area corresponding to a range indicated by reference numeral 20 among the area occupied by the flip-flop 210 in the first row of the standard cell SC2. Here, the first middle point may be a point where the right boundary of the range indicated by reference numeral 10 and the left boundary of the range indicated by reference numeral 20 in the drawing intersect each other. The actual position of the first middle point may be determined depending on a specific design purpose or design environment.

In an example, the first fixed length circuit may include one of the input and output pins of the flip-flop 210, and the first variable length circuit may include the other of the input and output pins of the flip-flop 210. For example, the first fixed length circuit may include the input pin D1 of the flip-flop 210, and the first variable length circuit may include the output pin Q1 of the flip-flop 210. In this case, the position of the first middle point may be determined between the input pin D1 and the output pin Q1 of the flip-flop 210. For example, although not illustrated, the first fixed length circuit may include the output pin Q1 of the flip-flop 210 and the first variable length circuit may include the input pin D1 of the flip-flop 210.

In an example, the flip-flop 220 may include a second fixed length circuit and a second variable length circuit defined in the same manner as defined in the flip-flop 210. Among the area occupied by the flip-flop 220 in the second row of the standard cell SC2, the second fixed length circuit may be represented by a circuit area corresponding to the range indicated by reference numeral 10, and the second variable length circuit may be represented by a circuit area corresponding to the range indicated by reference numeral 20. The point where the right boundary of the range indicated by reference number 10 in the second row and the left boundary of the range indicated by reference number 20 intersect each other may be defined as the second middle point. In an example, the second fixed length circuit may include one of the input and output pins of the flip-flop 220, and the second variable length circuit may include the other of the input and output pins of the flip-flop 220. For example, the second fixed length circuit may include the input pin D2 of the flip-flop 220, and the second variable length circuit may include the output pin Q2 of the flip-flop 220. In this case, the position of the second middle point may be determined between the input pin D2 and the output pin Q2 of the flip-flop 220. For example, although not illustrated, the second fixed length circuit may include the output pin Q2 of the flip-flop 220 and the second variable length circuit may include the input pin D2 of the flip-flop 220.

In an example, the flip-flop 230 may include a third fixed length circuit and a third variable length circuit defined in the same manner as defined in the flip-flop 210. Among the area occupied by the flip-flop 230 in the third row of the standard cell SC2, the third fixed length circuit may be represented as a circuit area corresponding to the range indicated by reference number 10.

Meanwhile, in the flip-flop 230, the third variable length circuit may be represented by a circuit area corresponding to the range indicated by reference numbers 20 and 30. In the case of the flip-flop 230, the length of the third variable length circuit may be longer by a predetermined length L₁ than the variable length circuits of the other flip-flops 210, 220, and 240, for example, to enhance drive strength. As illustrated in FIG. 2, reference numeral 30 indicates an extended area corresponding to the length L₁.

The third variable length circuit may include an upsizing circuit pattern. The upsizing circuit pattern may be a circuit pattern implemented to extend the width of the cell layout based on the variable length circuits of the other flip-flops 210, 220, and 240. Depending on the example, the upsizing circuit pattern may be implemented in various ways. For example, the upsizing circuit pattern may include increasing the width of the transistor or increasing the active area of the transistor, so that the width of the cell layout actually increases.

In an example, in order to implement the upsizing circuit pattern, the transistor may be increased in size by n times (where n is a positive real number). That is, the width of the transistor that is to be increased by n times in the actual cell layout may be increased by n times. In addition, a number of fins for the transistor may be adjusted n times depending on the changed width. In this case, diffusion sharing that shares the drain or source of the existing signal may be performed, and the number of dummy gates added may be n-1. In this case, the width of the cell may be extended by (n-1)*(contacted poly pitch). The length of the cell boundary may be extended according to the dummy gate placed at the outermost side among the added dummy gates. Furthermore, the transistor's fin and the transistor's well may be extended to the cell boundary, and the “Nselect” area and the “Pselect” area, which respectively represent NMOS (N-type Metal-Oxide-Semiconductor) and PMOS (P-type Metal-Oxide-Semiconductor), may also be extended. A “Gcut” representing “gate cut” may be added between the extended transistor and the cell boundary. In addition, the “Gcut” may be extended above and below the extended transistor to become a power rail area, and the metal to be used as a power rail may be extended to the cell boundary. Meanwhile, when the transistor is extended n times, the number of additional source-drain trenches (SDT) and local-interconnect source-drains (LISD) may be n−1 due to diffusion sharing that shares the drain or source of the existing signal. The length of the active layer may be extended so that the end portions of the additional SDTs and LISDs do not exceed the length. The local-interconnect gate (LIG), V0 via, and metal layer are connected so that the existing signal connection may be maintained the same, and the shape or position of LIG, LISD, V0, and metal may be changed to maintain the existing connection. Here, V0 may connect, for example, the LIG and the metal layer, or the LISD and the metal layer, and may typically represent a via placed at the lowest layer. For example, the upsizing circuit pattern may be designed such that the drive strength of the flip-flop 230 is twice the drive strength of the flip-flops 210, 220, and 240. Accordingly, as illustrated in FIG. 2, the flip-flop 210, the flip-flop 220, and the flip-flop 240 may have “1× drive strength”, and the flip-flop 230 may have “2× drive strength”. However, the scope of the present disclosure is not limited thereto, and an upsizing circuit pattern of any flip-flop may be designed such that the driving strength of the corresponding flip-flop is “a” times (a is a real number greater than 1) the driving strength of another flip-flop.

The point where the right boundary of the range indicated by reference number 10 in the third row and the left boundary of the range indicated by reference number 20 intersect each other may be defined as the third middle point. In an example, the third fixed length circuit may include one of the input and output pins of the flip-flop 230, and the third variable length circuit may include the other of the input and output pins of the flip-flop 230. For example, the third fixed length circuit may include the input pin D3 of the flip-flop 230, and the third variable length circuit may include the output pin Q3 of the flip-flop 230. In this case, the position of the third middle point may be determined between the input pin D3 and the output pin Q3 of the flip-flop 230. For example, unlike shown, it is also within the scope of the present disclosure that the third fixed length circuit includes the output pin Q3 of the flip-flop 230 and the third variable length circuit includes the input pin D3 of the flip-flop 230.

In an example, the flip-flop 240 may include a fourth fixed length circuit and a fourth variable length circuit defined in the same manner as defined in the flip-flop 210. Among the area occupied by the flip-flop 240 in the fourth row of the standard cell SC2, the fourth fixed length circuit may be represented by a circuit area corresponding to the range indicated by reference numeral 10, and the fourth variable length circuit may be represented by a circuit area corresponding to the range indicated by reference numeral 20. The point where the right boundary of the range indicated by reference number 10 in the fourth row and the left boundary of the range indicated by reference number 20 intersect each other may be defined as the fourth middle point. In an example, the fourth fixed length circuit may include one of the input and output pins of the flip-flop 240, and the fourth variable length circuit may include the other of the input and output pins of the flip-flop 240. For example, the fourth fixed length circuit may include the input pin D4 of the flip-flop 240, and the fourth variable length circuit may include the output pin Q4 of the flip-flop 240. In this case, the position of the fourth middle point may be determined between the input pin D4 and the output pin Q4 of the flip-flop 240. For example, unlike shown, it is also within the scope of the present disclosure that the fourth fixed length circuit includes the output pin Q4 of the flip-flop 240 and the fourth variable length circuit includes the input pin D4 of the flip-flop 240.

As illustrated in FIG. 2, the cell boundary CB of the standard cell SC2 may be defined to include a side (left side) extending in the second direction Y in the first fixed length circuit of the flip-flop 210, a side (left side) extending in the second direction Y in the second fixed length circuit of the flip-flop 220, a side (left side) extending in the second direction Y in the third fixed length circuit of the flip-flop 230, and a side (left side) extending in the second direction Y in the fourth fixed length circuit of the flip-flop 240. The cell boundary CB of the cell SC2 may be defined to additionally include a side (right side) extending in the second direction Y in the first variable length circuit of the flip-flop 210, a side (right side) extending in the second direction Y in the second variable length circuit of the flip-flop 220, a side (right side) extending in the second direction Y in the third variable length circuit of the flip-flop 230, and a side (right side) extending in the second direction Y in the fourth variable length circuit of the flip-flop 240. In addition, the cell boundary CB of the cell SC2 may be defined to additionally include a lower side of the flip-flop 210 and an upper side of the flip-flop 240.

Here, the side (left side) extending in the second direction Y in the first fixed length circuit of the flip-flop 210, the side (left side) extending in the second direction Y in the second fixed length circuit of the flip-flop 220, the side (left side) extending in the second direction Y in the third fixed length circuit of the flip-flop 230, and the side (left side) extending in the second direction Y in the fourth fixed length circuit of the flip-flop 210 may be aligned in a straight line with each other in the second direction Y.

Meanwhile, the side (right side) extending in the second direction Y in the first variable length circuit of the flip-flop 210, the side (right side) extending in the second direction Y in the second variable length circuit of the flip-flop 220, the side (right side) extending in the second direction Y in the third variable length circuit of the flip-flop 230, and the side (right side) extending in the second direction Y in the fourth variable length circuit of the flip-flop 240 may not be aligned in a straight line with each other in the second direction Y. That is, the side (right side) extending in the second direction Y in the third variable length circuit of the flip-flop 230 may be misaligned in the second direction with the side (right side) extending in the second direction Y in the first variable length circuit of the flip-flop 210, the side (right side) extending in the second direction Y in the second variable length circuit of the flip-flop 220, and the side (right side) extending in the second direction Y in the fourth variable length circuit of the flip-flop 240.

In an example, in the cell layout of the multi-bit flip-flop, since the cell boundary is formed so that the width of the third row is different from the widths of the first row, the second row, and the fourth row, an unnecessary empty space occurring in an existing rectangular-shaped cell may not be formed. That is, when the standard cell SC2 is implemented to have a conventional rectangular shape, in the drawing, the area corresponding to the range indicated by reference number 30 for the first row, the second row, and the fourth row will be included in the standard cell SC2 as an empty space, but in the present example, the area is outside the standard cell SC2, so it may be utilized, such as by placing another cell in the corresponding area.

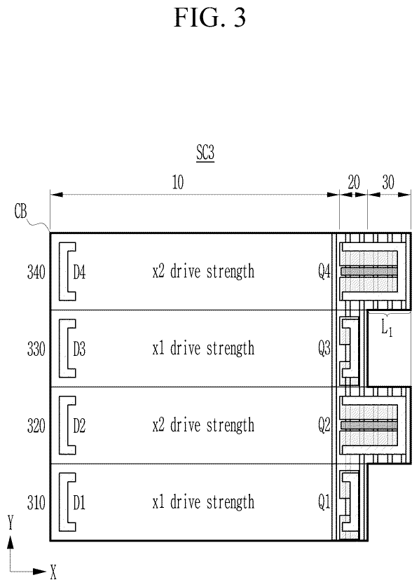

FIG. 3 illustrates an example semiconductor circuit according to one or more embodiments.

Referring to FIG. 3, in a non-limiting example, a semiconductor circuit may include a standard cell SC3 defining a multi-bit flip-flop. The standard cell SC3 may include a plurality of flip-flops 310, 320, 330, and 340. Hereinafter, differences from the embodiment of FIG. 2 will be mainly described, and for contents not explicitly described, reference may be made to contents explicitly described in other examples described in the present specification.

In an example, the flip-flop 310 may be placed in the first row within the standard cell SC3 to extend along the first direction X, and the flip-flop 320 may be placed in the second row within the standard cell SC3 to extend parallel to the flip-flop 310 along the first direction X. The flip-flop 330 may be placed in the third row within the standard cell SC3 to extend parallel to the flip-flop 310 and the flip-flop 320 along the first direction X, and the flip-flop 340 may be placed in the fourth row within the standard cell SC3 to extend parallel to the flip-flop 310 to the flip-flop 330 along the first direction X. In an example, the flip-flop 310 and the flip-flop 320 may be placed directly adjacent to each other while sharing at least a clock generation circuit. In addition, the flip-flop 330 and the flip-flop 340 may also be placed directly adjacent to each other while sharing at least a clock generation circuit.

The flip-flop 310 may include a first fixed length circuit and a first variable length circuit, and the first fixed length circuit may represent a circuit area corresponding to a range indicated by reference numeral 10 among areas occupied by the flip-flop 310 in the first row of the standard cell SC3, and the first variable length circuit may represent a circuit area corresponding to a range indicated by reference numeral 20 among areas occupied by the flip-flop 310 in the first row of the standard cell SC3.

In an example, the flip-flop 320 may include a second fixed length circuit and a second variable length circuit, and the second fixed length circuit may represent a circuit area corresponding to a range indicated by reference numeral 10 among areas occupied by the flip-flop 320 in the second row of the standard cell SC3, and the second variable length circuit may represent a circuit area corresponding to a range indicated by reference numerals 20 and 30 among areas occupied by the flip-flop 320 in the second row of the standard cell SC3. The second variable length circuit may include an upsizing circuit pattern implemented to extend the width by the length L₁ based on the variable length circuits of the flip-flop 310 and the flip-flop 330. The upsizing circuit pattern of the second variable length circuit may be designed such that the drive strength of the flip-flop 320 is twice the drive strength of the flip-flop 310 and the flip-flop 330. Accordingly, as illustrated in FIG. 3, the flip-flop 310 and the flip-flop 330 may have “1× drive strength”, and the flip-flop 320 may have “2× drive strength”.

In an example, the flip-flop 330 may include a third fixed length circuit and a third variable length circuit, and the third fixed length circuit may represent a circuit area corresponding to a range indicated by reference numeral 10 among areas occupied by the flip-flop 330 in the third row of the standard cell SC3, and the third variable length circuit may represent a circuit area corresponding to a range indicated by reference numeral 20 among areas occupied by the flip-flop 330 in the third row of the standard cell SC3.

In an example, the flip-flop 340 may include a fourth fixed length circuit and a fourth variable length circuit, and the fourth fixed length circuit may represent a circuit area corresponding to a range indicated by reference numeral 10 among areas occupied by the flip-flop 340 in the fourth row of the standard cell SC3, and the fourth variable length circuit may represent a circuit area corresponding to a range indicated by reference numerals 20 and 30 among areas occupied by the flip-flop 340 in the fourth row of the standard cell SC3. The fourth variable length circuit may include an upsizing circuit pattern implemented to extend the width by the length L₁ based on the variable length circuits of the flip-flop 310 and the flip-flop 330. The upsizing circuit pattern of the fourth variable length circuit may be designed such that the drive strength of the flip-flop 340 is twice the drive strength of the flip-flop 310 and the flip-flop 330. Accordingly, as illustrated in FIG. 3, the flip-flop 310 and the flip-flop 330 may have “1× drive strength”, and the flip-flop 340 may have “2× drive strength”.

In addition, in the cell boundary CB of the standard cell SC3, the side (right side) extending in the second direction Y in the second variable length circuit of the flip-flop 320 may be configured to be misaligned in the second direction Y with the side (right side) extending in the second direction Y in the first variable length circuit of the flip-flop 310 and the side (right side) extending in the second direction Y in the third variable length circuit of the flip-flop 330. Meanwhile, the side (right side) extending in the second direction Y in the fourth variable length circuit of the flip-flop 340 may be configured to be misaligned in the second direction Y with the side (right side) extending in the second direction Y in the first variable length circuit of the flip-flop 310 and the side (right side) extending in the second direction Y in the third variable length circuit of the flip-flop 330. Meanwhile, the side (left side) extending in the second direction Y in the second fixed length circuit of the flip-flop 320 and the side (left side) extending in the second direction Y in the fourth fixed length circuit of the flip-flop 340 may form a straight line with each other in the second direction Y.

In an example, when the standard cell SC3 is implemented to have a conventional rectangular shape, as illustrated in FIG. 3, the area corresponding to the range indicated by reference number 30 for the first row and the third row will be included in the standard cell SC3 as an empty space, but in the present example, the area is outside the standard cell SC3, so it may be utilized, such as by placing another cell in the corresponding area.

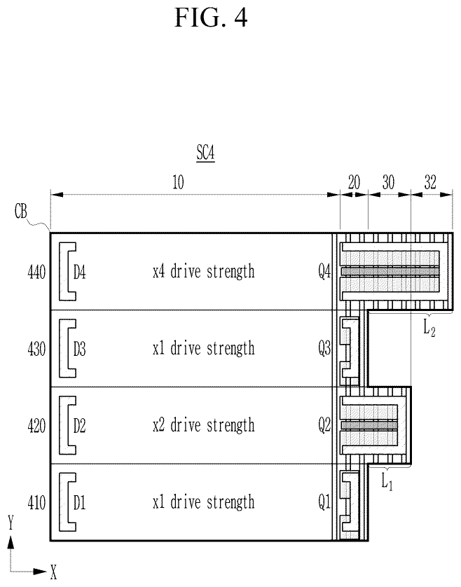

FIG. 4 illustrates an example semiconductor circuit according to one or more embodiments.

Referring to FIG. 4, in a non-limiting example, a semiconductor circuit may include a standard cell SC4 defining a multi-bit flip-flop. The standard cell SC4 may include a plurality of flip-flops 410, 420, 430, and 440. Hereinafter, differences from the embodiment of FIG. 3 will be mainly described, and for contents not explicitly described, reference may be made to contents explicitly described in other embodiments described in the present specification.

In an example, the flip-flop 410 may include a first fixed length circuit and a first variable-length circuit, the flip-flop 420 may include a second fixed length circuit and a second variable length circuit, and the flip-flop 430 may include a third fixed length circuit and a third variable length circuit, and reference may be made to the description provided earlier with respect to FIG. 3 for further details.

In an example, the flip-flop 440 may include a fourth fixed length circuit and a fourth variable length circuit, and the fourth fixed length circuit may represent a circuit area corresponding to a range indicated by reference numeral 10 among areas occupied by the flip-flop 440 in the fourth row of the standard cell SC4, and the fourth variable length circuit may represent a circuit area corresponding to a range indicated by reference numerals 20 and 30 among areas occupied by the flip-flop 440 in the fourth row of the standard cell SC4. The fourth variable length circuit may include an upsizing circuit pattern implemented to extend the width by the length L₂ based on the variable length circuits of the flip-flop 410 and the flip-flop 430. Here, the length L₂ may be set to be longer than the length L₁. The upsizing circuit pattern of the fourth variable length circuit may be designed such that the drive strength of the flip-flop 440 is four times the drive strength of the flip-flop 410 and the flip-flop 430. Accordingly, as illustrated in FIG. 4, the flip-flop 410 and the flip-flop 430 may have “1× drive strength”, and the flip-flop 440 may have “4× drive strength”. That is, the upsizing circuit pattern of a certain flip-flop may be designed such that the drive strength of the corresponding flip-flop is “a” times the drive strength of the another flip-flop (“a” is a real number greater than 1), and the upsizing circuit pattern of another flip-flop may be designed such that the drive strength of the corresponding flip-flop is “b” times the drive strength of the another flip-flop (“b” is a real number greater than “a”).

As illustrated in FIG. 4, in the cell boundary CB of the standard cell SC4, the side (right side) extending in the second direction Y in the second variable length circuit of the flip-flop 420 may be configured to be misaligned in the second direction Y with all of the side (right side) extending in the second direction Y in the first variable length circuit of the flip-flop 410, the side (right side) extending in the second direction Y in the third variable length circuit of the flip-flop 430, and the side (right side) extending in the second direction Y in the fourth variable length circuit of the flip-flop 440. Meanwhile, the side (right side) extending in the second direction Y in the fourth variable length circuit of the flip-flop 440 may be configured to be misaligned in the second direction with the side (right side) extending in the second direction Y in the first variable length circuit of the flip-flop 410, the side (right side) extending in the second direction Y in the second variable length circuit of the flip-flop 420, and the side (right side) extending in the second direction Y in the third variable length circuit of the flip-flop 430.

In an example, when the standard cell SC4 is implemented to have a conventional rectangular shape, as illustrated in FIG. 4, the area corresponding to the range indicated by reference numbers 30 and 32 for the first and third rows, and the area corresponding to the range indicated by reference number 32 for the second row will be included in the standard cell SC4 as an empty space, but in the present example, the area is outside the standard cell SC4, so it may be utilized, such as by placing another cell in the corresponding area.

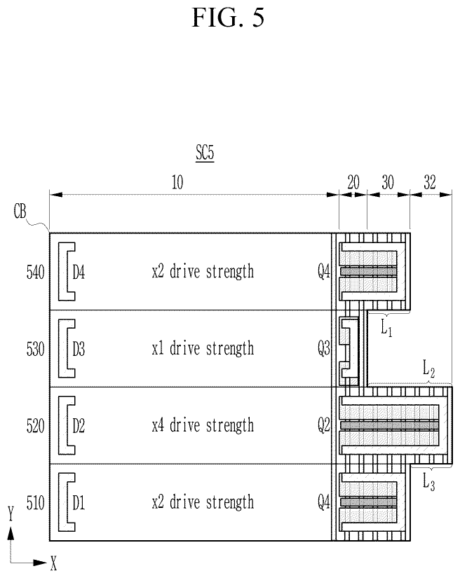

FIG. 5 illustrates an example semiconductor circuit according to one or more embodiments.

Referring to FIG. 5, in a non-limiting example, a semiconductor circuit may include a standard cell SC5 defining a multi-bit flip-flop. The standard cell SC5 may include a plurality of flip-flops 510, 520, 530, and 540. Hereinafter, differences from the embodiment of FIG. 3 will be mainly described, and for contents not explicitly described, reference may be made to contents explicitly described in other embodiments described in the present specification.

In an example, the flip-flop 530 may include a third fixed length circuit and a third variable-length circuit, and the flip-flop 540 may include a fourth fixed length circuit and a fourth variable length circuit, and reference may be made to the description provided earlier with respect to FIG. 3 as described above for further details.

In an example, the flip-flop 510 may include a first fixed length circuit and a first variable length circuit, and the first fixed length circuit may represent a circuit area corresponding to a range indicated by reference numeral 10 among areas occupied by the flip-flop 510 in the first row of the standard cell SC5, and the first variable length circuit may represent a circuit area corresponding to a range indicated by reference numerals 20 and 30 among areas occupied by the flip-flop 510 in the first row of the standard cell SC5. The first variable length circuit may include an upsizing circuit pattern implemented to extend the width by the length L₁ based on the variable length circuits of the flip-flop 530. The upsizing circuit pattern of the first variable length circuit may be designed so that the drive strength of the flip-flop 510 is twice the drive strength of the flip-flop 530. Accordingly, as illustrated in FIG. 5, the flip-flop 530 may have “1× drive strength”, and the flip-flop 510 may have “2× drive strength”.

In an example, the flip-flop 520 may include a second fixed length circuit and a second variable length circuit, and the second fixed length circuit may represent a circuit area corresponding to a range indicated by reference numeral 10 among areas occupied by the flip-flop 520 in the second row of the standard cell SC5, and the second variable length circuit may represent a circuit area corresponding to a range indicated by reference numerals 20, 30, and 32 among areas occupied by the flip-flop 520 in the second row of the standard cell SC5. The second variable length circuit may include an upsizing circuit pattern implemented to extend the width by the length L₂ based on the variable length circuit of the flip-flop 530 and to extend the width by length L₃ based on the variable length circuit of the flip-flop 510. Here, the length L₂ may be set to be the sum of the length L₁ and the length L₃. The upsizing circuit pattern of the second variable length circuit may be designed such that the drive strength of the flip-flop 520 is four times the drive strength of the flip-flop 530. Accordingly, as shown in the drawing, the flip-flop 530 may have “1× drive strength”, and the flip-flop 520 may have “4× drive strength”.

As illustrated in FIG. 5, in the cell boundary CB of the standard cell SC5, the side (right side) extending in the second direction Y in the second variable length circuit of the flip-flop 520 may be configured to be misaligned in the second direction Y with all of the side (right side) extending in the second direction Y in the first variable length circuit of the flip-flop 510, the side (right side) extending in the second direction Y in the third variable length circuit of the flip-flop 530, and the side (right side) extending in the second direction Y in the fourth variable length circuit of the flip-flop 540. Meanwhile, the side (right side) extending in the second direction Y in the first variable length circuit of the flip-flop 510 may be configured to be misaligned in the second direction Y with both the side (right side) extending in the second direction Y in the second variable length circuit of the flip-flop 520 and the side (right side) extending in the second direction Y in the third variable length circuit of the flip-flop 530. Meanwhile, the side (left side) extending in the second direction Y in the first fixed length circuit of the flip-flop 510 and the side (left side) extending in the second direction Y in the fourth fixed length circuit of the flip-flop 540 may form a straight line with each other in the second direction Y.

In an example, when the standard cell SC5 is implemented to have a conventional rectangular shape, in the drawing, the area corresponding to the range indicated by reference numbers 30 and 32 for the third row, and the area corresponding to the range indicated by reference number 32 for the first and second rows will be included in the standard cell SC5 as an empty space, but in the present example, the area is outside the standard cell SC5, so it may be utilized, such as by placing another cell in the corresponding area.

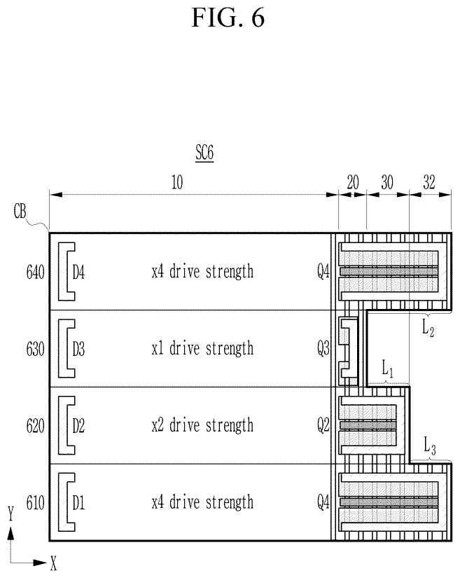

FIG. 6 illustrates an example semiconductor circuit according to one or more embodiments.

Referring to FIG. 6, in a non-limiting example, a semiconductor circuit may include a standard cell SC6 defining a multi-bit flip-flop. The standard cell SC6 may include a plurality of flip-flops 610, 620, 630, and 640. Hereinafter, differences from the embodiment of FIG. 4 will be mainly described, and for contents not explicitly described, reference may be made to contents explicitly described in other embodiments described in the present specification.

In an example, the flip-flop 620 may include a second fixed length circuit and a second variable-length circuit, the flip-flop 630 may include a third fixed length circuit and a third variable length circuit, and the flip-flop 640 may include a fourth fixed length circuit and a fourth variable length circuit, and reference may be made to the description provided earlier with respect to FIG. 3 for further details.

In an example, the flip-flop 610 may include a first fixed length circuit and a first variable length circuit, and the first fixed length circuit may represent a circuit area corresponding to a range indicated by reference numeral 10 among areas occupied by the flip-flop 610 in the first row of the standard cell SC6, and the first variable length circuit may represent a circuit area corresponding to a range indicated by reference numerals 20, 30, and 32 among areas occupied by the flip-flop 610 in the first row of the standard cell SC6. The first variable length circuit may include an upsizing circuit pattern implemented to extend the width by the length L₂ based on the variable length circuit of the flip-flop 630 and to extend the width by length L₃ based on the variable length circuit of the flip-flop 620. Here, the length L₂ may be set to be the sum of the length L₁ and the length L₃. The upsizing circuit pattern of the first variable length circuit may be designed so that the drive strength of the flip-flop 610 is four times the drive strength of the flip-flop 630. Accordingly, as illustrated in FIG. 6, the flip-flop 630 may have “1× drive strength”, and the flip-flop 610 may have “4× drive strength”.

As illustrated in FIG. 6, in the cell boundary CB of the standard cell SC6, the side (right side) extending in the second direction Y in the second variable length circuit of the flip-flop 620 may be configured to be misaligned in the second direction Y with all of the side (right side) extending in the second direction Y in the first variable length circuit of the flip-flop 610, the side (right side) extending in the second direction Y in the third variable length circuit of the flip-flop 630, and the side (right side) extending in the second direction Y in the fourth variable length circuit of the flip-flop 640. Meanwhile, the side (right side) extending in the second direction Y in the first variable length circuit of the flip-flop 610 may be configured to be misaligned in the second direction Y with both the side (right side) extending in the second direction Y in the second variable length circuit of the flip-flop 620 and the side (right side) extending in the second direction Y in the third variable length circuit of the flip-flop 630. Meanwhile, the side (left side) extending in the second direction Y in the first fixed length circuit of the flip-flop 610 and the side (left side) extending in the second direction Y in the fourth fixed length circuit of the flip-flop 640 may form a straight line with each other in the second direction Y.

In an example, when the standard cell SC6 is implemented to have a conventional rectangular shape, in the drawing, the area corresponding to the range indicated by reference numbers 30 and 32 for the third row, and the area corresponding to the range indicated by reference number 32 for the second row will be included in the standard cell SC6 as an empty space, but in the present example, the area is outside the standard cell SC6, so it may be utilized, such as by placing another cell in the corresponding area.

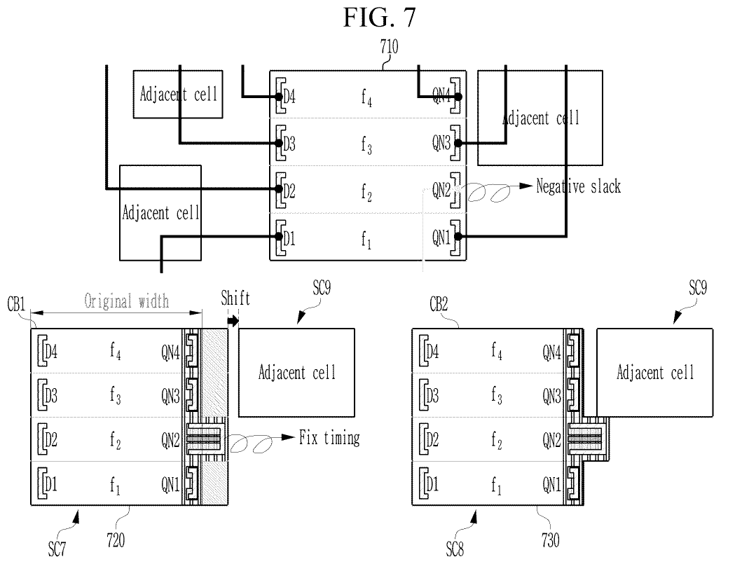

FIG. 7 illustrates example semiconductor circuits according to one or more embodiments.

Referring to FIG. 7, in a non-limiting example, in order to correct a timing violation, a method of replacing a cell instance with a cell instance having a stronger output of a driving strength may be used. However, because of the large area of a multi-bit flip-flop, in order to replace an instance of a multi-bit flip-flop with a timing violation, significant disturbances may occur in cell placement and net routing, which may be present a large burden in the design of semiconductor circuits. For example, as illustrated in FIG. 7, circuit 720 shows that the cell instance SC9 adjacent to the multi-bit flip-flop instance must be moved to the right to make a space to accommodate a multi-bit flip-flop cell SC7 with a stronger driving strength to correct the timing violation as shown in circuit 710. Here, it may be seen that an unnecessary empty space ES is included in the cell boundary CB1 of the multi-bit flip-flop cell SC7. On the other hand, in the case of a multi-bit flip-flop cell SC8 having a layout according to the examples described above, in circuit 730, the adjacent cell instance SC9 does not need to move, so it is possible to avoid disturbance to the route connected to the cell instance SC9. Here, it may be seen that an unnecessary empty space is not included in the cell boundary CB2 of the multi-bit flip-flop cell SC8.

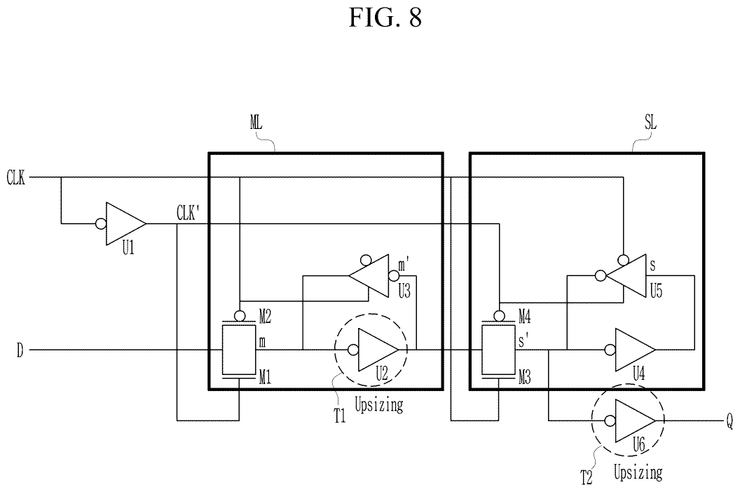

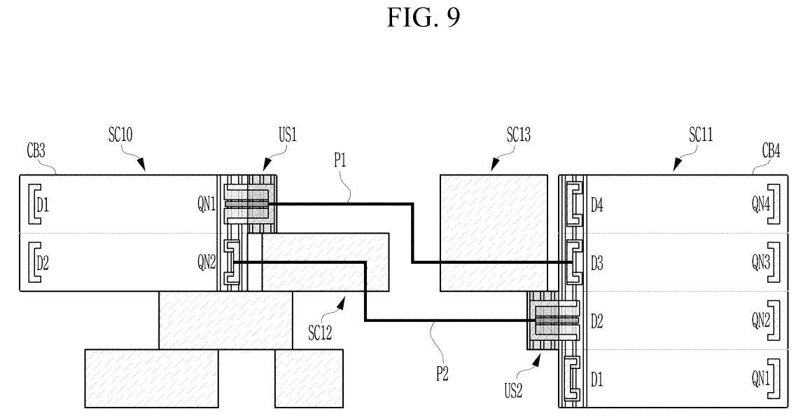

FIG. 8 and FIG. 9 illustrate example electronic devices with timing violation resolution according to one or more embodiments.

Referring to FIG. 8 and FIG. 9, in non-limiting examples, in the post-route step, the size of the internal flip-flop may be selectively extended to optimize the timing of the multi-bit flip-flop instance while maintaining the already optimized placement and route. To this end, as illustrated in FIG. 8, the transistors within the flip-flop may be selectively upsized to prepare multi-bit flip-flop cells having various cell boundary shapes according to the embodiments.

For example, the transistor T1 of the master latch ML may be upsized or the transistor T2 of the slave latch SL may be upsized.

Next, referring to FIG. 9, it is possible to attempt to correct the timing by replacing the multi-bit flip-flop instance related to the timing violation with the prepared multi-bit flip-flop cell, or to attempt to reduce the negative time slack as much as possible at the expense of a minimal increase in power overhead. For example, if there are paths P1 and P2 of setup time violation between multi-bit flip-flop cells, a multi-bit flip-flop cell SC10 including an upsizing circuit pattern US1 generated by upsizing a transistor T2 of a slave latch SL and having a cell boundary CB3 accordingly may be prepared. In addition, a multi-bit flip-flop cell SC11 including an upsizing circuit pattern US2 generated by upsizing a transistor T1 of a master latch ML and having a cell boundary CB4 accordingly may be prepared. By replacing the multi-bit flip-flop instance associated with the timing violation with the multi-bit flip-flop cell SC10 and the multi-bit flip-flop cell SC11, timing optimizations may be performed to correct timing violations without causing movement or disturbance to adjacent cell instances (SC12, SC13), that is, while maintaining the already optimized placement and route.

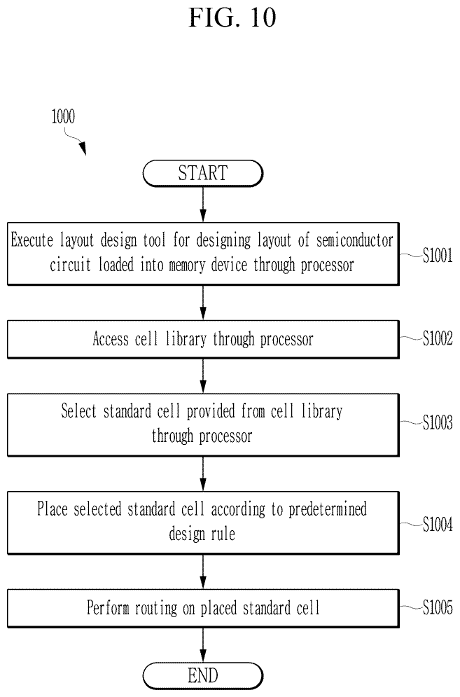

FIG. 10 illustrates an example method for designing a semiconductor circuit according to one or more embodiments.

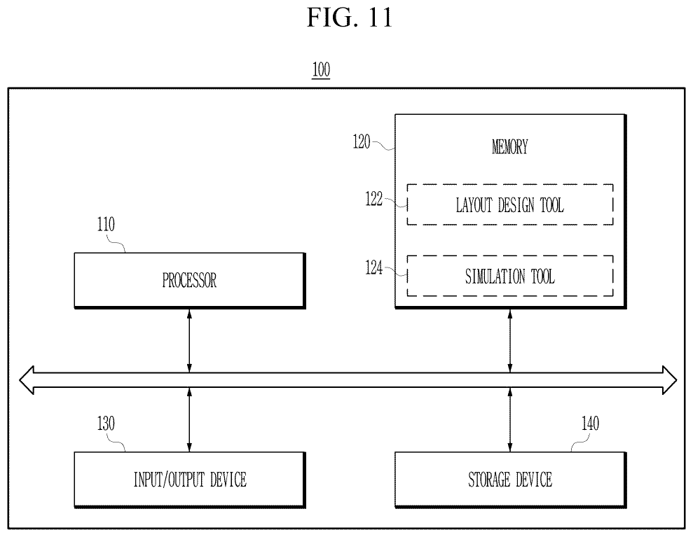

Referring to FIG. 10, in a non-limiting example, the method 1000 for designing the semiconductor circuit may include executing a layout design tool for designing the layout of a semiconductor circuit loaded into a memory device through a processor (e.g., processor 110 of FIG. 11) in operation S1001; accessing a cell library through the processor in operation 1002; selecting a standard cell provided from the cell library through the processor in operation S1003; placing the selected standard cell according to a predetermined design rule in operation S1004; and performing routing on the placed standard cell in operation S1005.

In an example, in operation S1003, the standard cell may have a cell boundary formed according to the width of each single bit flip-flop when the widths of the single bit flip-flop vary in a plurality of rows in the cell layout of the multi-bit flip-flop according to the examples described above in the present specification.

For more detailed descriptions on the method for designing the semiconductor circuit according to examples, reference may be made to the descriptions of the examples described herein, so redundant descriptions thereof will be omitted.

FIG. 11 illustrates an example electronic system according to one or more embodiments.

Referring to FIG. 11, in a non-limiting example, an electronic system for designing semiconductor circuit 100 may include at least one processor 110, a memory 120, an input/output device 130, and a storage device 140. Here, the electronic system 100 may be provided as a computing device for designing the layout of the semiconductor circuit according to the examples. In addition, the electronic system 100 may be configured to run various design and verification simulation programs.

The processor 110 may be configured to execute programs or applications to configure the processor 110 to control the electronic system 100 to perform one or more or all operations and/or methods involving the semiconductor circuit design. The processor 110 may execute software, for example, application programs, operating systems, and device drivers to be run on the electric system 100. The processor 110 may execute an operating system loaded into the memory 120. The processor 110 may execute various application programs to operate based on the operating system. For example, the processor 110 may execute a layout design tool 122 loaded in the memory 120.

An operating system or an application program may be loaded into the memory 120. When the electric system 100 is booted, an image of an operating system stored in the storage device 140 may be loaded into the memory 120 according to the booting sequence. All input/output operations of the electric system 100 may be supported by the operating system. Similarly, application programs may be loaded into the memory 120 to be selected by the user or to provide basic services. Particularly, the layout design tool 122 for layout design of a semiconductor circuit may also be loaded into the memory 120 from the storage device 140.

The layout design tool 122 may be provided with a biasing function that may change the shape and position of specific layout patterns differently from those defined by design rules. In addition, the layout design tool 122 may perform design rule check (DRC) under changed biasing data conditions. The memory 120 may include a volatile memory such as a static random access memory (SRAM) or a dynamic random access memory (DRAM). However, the memory 120 is not limited thereto, and may include a nonvolatile memory such as a phase-change RAM (PRAM), a magnetic random access memory (MRAM), a resistance RAM (ReRAM), a ferroelectric RAM (FRAM), and a flash memory. A simulation tool 124 for performing optical proximity correction (OPC) on the designed layout data may be additionally loaded into the memory 120.

The input/output device 130 may include various devices that may receive information from the designer or provide information to the designer, such as a keyboard, mouse, or monitor. For example, a processing process and a processing result of the simulation tool 124 may be displayed through the input/output device 130.

The storage device 140 may be provided as a storage medium of the electric system 100. The storage device 140 may store application programs, operating system images, and various data. For example, the storage device 140 may be provided as a solid state drive (SSD), an embedded multi-media card (eMMC), or a hard disk drive (HDD). The storage device 140 may include a NAND flash memory. However, the present disclosure is not limited thereto, and the storage device 140 may include a nonvolatile memory such as PRAM, MRAM, ReRAM, FRAM, or the like, or a NOR flash memory.

The processor 110 may execute the layout design tool 122 to place or route the standard cell provided from the cell library according to a predetermined design rule, and the standard cell may have a cell boundary formed according to the width of each single bit flip-flop when the widths of the single bit flip-flop vary in a plurality of rows in the cell layout of the multi-bit flip-flop according to the embodiments described in the present specification.

According to the above examples, the cell boundary may be formed according to the width of each single-bit flip-flop in cases where the widths of the single-bit flip-flops vary across multiple rows in the cell layout of a multi-bit flip-flop, so that another cell may be placed in the unnecessary empty space that has occurred in an existing rectangular-shaped cell. This may reduce wasted space throughout the semiconductor chip.

The electronic devices, electronic systems, processors, memories, semiconductor circuits, standard cells SC1-SC14, electronic system 100, processor 110, memory 120, input/output device 130, and storage device 140 described herein, including descriptions with respect to respect to FIGS. 1-11, are implemented by or representative of hardware components. As described above, or in addition to the descriptions above, examples of hardware components that may be used to perform the operations described in this application where appropriate include controllers, sensors, generators, drivers, memories, comparators, arithmetic logic units, adders, subtractors, multipliers, dividers, integrators, and any other electronic components configured to perform the operations described in this application. In other examples, one or more of the hardware components that perform the operations described in this application are implemented by computing hardware, for example, by one or more processors or computers. A processor or computer may be implemented by one or more processing elements, such as an array of logic gates, a controller and an arithmetic logic unit (ALU), a digital signal processor (DSP), a microcomputer, a programmable logic controller, a field-programmable gate array (FPGA), a programmable logic array (PLU), a microprocessor, or any other device or combination of devices that is configured to respond to and execute instructions (e.g., code or coding) in a defined manner to achieve a desired result. In one example, a processor or computer includes, or is connected to, one or more memories storing the instructions or software that are executed by the processor or computer. Hardware components implemented by a processor or computer may execute the instructions or software, such as an operating system (OS) and one or more software applications that run on the OS, to perform the operations described in this application. The hardware components may also access, manipulate, process, create, and store data in response to execution of the instructions or software. For simplicity, the singular term “processor” or “computer” may be used in the description of the examples described in this application, but in other examples multiple processors or computers may be used, or a processor or computer may include multiple processing elements, or multiple types of processing elements, or both, and thus while some references may be made to a singular processor or computer, such references also are intended to refer to multiple processors or computers. For example, a single hardware component or two or more hardware components may be implemented by a single processor, or two or more processors, or a processor and a controller. One or more hardware components may be implemented by one or more processors, or a processor and a controller, and one or more other hardware components may be implemented by one or more other processors, or another processor and another controller. One or more processors, or a processor and a controller, may implement a single hardware component, or two or more hardware components. As described above, or in addition to the descriptions above, example hardware components may have any one or more of different processing configurations, examples of which include a single processor, independent processors, parallel processors, single-instruction single-data (SISD) multiprocessing, single-instruction multiple-data (SIMD) multiprocessing, multiple-instruction single-data (MISD) multiprocessing, and multiple-instruction multiple-data (MIMD) multiprocessing. Thus, references to a processor herein mean processing circuitry (e.g., circuitry that includes one or more processing element(s) circuits). One or more processors comprising processing circuitry also refers to each processor comprising processing circuitry, as well as some or all of the one or more processors comprising the same processing circuitry. In addition, processors(s) and controller(s), as a non-limiting example, do not mean human processing or human control, but rather, refer to hardware components as described herein, as non-limiting examples.

The methods illustrated in, and discussed with respect to, FIGS. 1-11 that perform the operations described in this application are performed by computing hardware, for example, by one or more processors or computers, implemented as described above implementing the instructions (e.g., computer or processor/processing device readable instructions) or software to perform the operations described in this application that are performed by the methods. For example, a single operation or two or more operations may be performed by a single processor, or two or more processors, or a processor and a controller. One or more operations may be performed by one or more processors, or a processor and a controller, and one or more other operations may be performed by one or more other processors, or another processor and another controller. One or more processors, or a processor and a controller, may perform a single operation, or two or more operations. References to a processor, or one or more processors, as a non-limiting example, configured to perform two or more operations refers to a processor or two or more processors being configured to collectively perform all of the two or more operations, as well as a configuration with the two or more processors respectively performing any corresponding one of the two or more operations (e.g., with a respective one or more processors being configured to perform each of the two or more operations, or any respective combination of one or more processors being configured to perform any respective combination of the two or more operations). Likewise, a reference to a processor-implemented method is a reference to a method that is performed by one or more processors or other processing or computing hardware of a device or system.

The instructions or software to control computing hardware, for example, one or more processors or computers, to implement the hardware components and perform the methods as described above may be written as computer programs, code segments, or other executable instructions or any combination thereof, for individually or collectively instructing or configuring the one or more processors or computers to operate as a machine or special-purpose computer to perform the operations that are performed by the hardware components and the methods as described above. In one example, the instructions or software include machine code that is directly executed by the one or more processors or computers, such as machine code produced by a compiler. In another example, the instructions or software includes higher-level code that is executed by the one or more processors or computer using an interpreter. The instructions or software may be written using any programming language based on the block diagrams and the flow charts illustrated in the drawings and the corresponding descriptions herein, which disclose algorithms for performing the operations that are performed by the hardware components and the methods as described above.

The instructions or software to control computing hardware, for example, one or more processors or computers, to implement the hardware components and perform the methods as described above, and any associated data, data files, and data structures, may be recorded, stored, or fixed in or on one or more non-transitory computer-readable storage media, and thus, not a signal per se. Thus, references herein to storage media mean storage media hardware, and does not mean to transitory media, nor a signal per se. As described above, or in addition to the descriptions above, examples of a non-transitory computer-readable storage medium include one or more of any of read-only memory (ROM), random-access programmable read only memory (PROM), electrically erasable programmable read-only memory (EEPROM), random-access memory (RAM), dynamic random access memory (DRAM), static random access memory (SRAM), flash memory, non-volatile memory, CD-ROMs, CD-Rs, CD+Rs, CD-RWs, CD+RWs, DVD-ROMs, DVD-Rs, DVD+Rs, DVD-RWs, DVD+RWs, DVD-RAMs, BD-ROMs, BD-Rs, BD-R LTHs, BD-REs, blue-ray or optical disk storage, hard disk drive (HDD), solid state drive (SSD), flash memory, a card type memory such as a multimedia card or a micro card (for example, secure digital (SD) or extreme digital (XD)), magnetic tapes, floppy disks, magneto-optical data storage devices, optical data storage devices, hard disks, solid-state disks, and/or any other device that is configured to store the instructions or software and any associated data, data files, and data structures in a non-transitory manner and provide the instructions or software and any associated data, data files, and data structures to one or more processors or computers so that the one or more processors or computers can execute the instructions. In one example, the instructions or software and any associated data, data files, and data structures are distributed over network-coupled computer systems so that the instructions and software and any associated data, data files, and data structures are stored, accessed, and executed in a distributed fashion by the one or more processors or computers.

While this disclosure includes specific examples, it will be apparent after an understanding of the disclosure of this application that various changes in form and details may be made in these examples without departing from the spirit and scope of the claims and their equivalents. The examples described herein are to be considered in a descriptive sense only, and not for purposes of limitation. Descriptions of features or aspects in each example are to be considered as being applicable to similar features or aspects in other examples. Suitable results may be achieved if the described techniques are performed in a different order, and/or if components in a described system, architecture, device, or circuit are combined in a different manner, and/or replaced or supplemented by other components or their equivalents.

Therefore, in addition to the above and all drawing disclosures, the scope of the disclosure is also inclusive of the claims and their equivalents, i.e., all variations within the scope of the claims and their equivalents are to be construed as being included in the disclosure.

What is claimed is:

1. A semiconductor circuit, comprising:
a first flip-flop configured to extend along a first direction; and
a second flip-flop configured to extend parallel to the first flip-flop along the first direction,
wherein the first flip-flop comprises:
a first fixed length circuit including one of input/output pins of the first flip-flop; and
a first variable length circuit including another of the input/output pins of the first flip-flop,
wherein the second flip-flop comprises:
a second fixed length circuit including one of input/output pins of the second flip-flop; and
a second variable length circuit including the other of the input/output pins of the second flip-flop, and
wherein a second length of the second variable length circuit in the first direction is configured to be longer by a predetermined first length than a first length of the first variable length circuit in the first direction.

2. The semiconductor circuit of claim 1, wherein a first side extending in a second direction perpendicular to the first direction defined by a cell boundary of a multi-bit flip-flop cell layout of the semiconductor circuit in the first variable length circuit is configured to be misaligned with a second side extending in the second direction defined by the cell boundary in the second variable length circuit, and
wherein the multi-bit flip-flop cell layout includes the first flip-flop and the second flip-flop.

3. The semiconductor circuit of claim 2, wherein the first side is configured to form a straight line with the second side.

4. The semiconductor circuit of claim 1, wherein the second variable length circuit includes a first upsizing circuit pattern extending a width of a cell layout with respect to the first variable length circuit.

5. The semiconductor circuit of claim 4, wherein the first upsizing circuit pattern is configured to have a second drive strength of the second flip-flop be “a” times of a first drive strength of the first flip-flop, and
wherein “a” is a real number greater than 1.

6. The semiconductor circuit of claim 1, further comprising:
a clock generation circuit,
wherein the first flip-flop and the second flip-flop are placed directly adjacent to each other while sharing the clock generation circuit.

7. The semiconductor circuit of claim 1, further comprising:
a third flip-flop configured to extend parallel to the first flip-flop and the second flip-flop along the first direction, wherein the third flip-flop comprises:
a third fixed length circuit including one of input/output pins of the third flip-flop; and
a third variable length circuit including the other of the input/output pins of the third flip-flop, and
wherein a third length of the third variable length circuit in the first direction is configured to be longer by a predetermined second length than a first length of the first variable length circuit in the first direction.

8. The semiconductor circuit of claim 7, wherein a first side extending in a second direction perpendicular to the first direction defined by a cell boundary of a multi-bit flip-flop cell layout including the first flip-flop and the second flip-flop in the first variable length circuit, a second side extending in the second direction defined by the cell boundary in the second variable length circuit, and a third side extending in the second direction defined by the cell boundary in the third variable length circuit are configured to be misaligned with each other.

9. The semiconductor circuit of claim 7, wherein the third variable length circuit includes a second upsizing circuit pattern extending a width of a cell layout with respect to the first variable length circuit.

10. The semiconductor circuit of claim 9, wherein the second upsizing circuit pattern is configured to have a third drive strength of the third flip-flop be “b” times a first drive strength of the first flip-flop, and
wherein “b” is a real number greater than a ratio “a”, the ratio “a” being a second drive strength of the second flip-flop to the first drive strength.

11. A semiconductor circuit design system, comprising:
one or more processors comprising processing circuitry;
a memory comprising one or more storage media storing a layout design tool, the layout design tool being configured to design a layout of a semiconductor circuit and instructions that, when executed individually or collectively by the one or more processors, cause the semiconductor circuit design system to:
place a standard cell provided from a cell library according to a predetermined design rule, the standard cell including a multi-bit flip-flop cell layout, the multi-bit flip-flop cell layout including:
a first flip-flop formed to extend along a first direction, and
a second flip-flop formed to extend parallel to the first flip-flop along the first direction,
wherein the first flip-flop comprises:
a first fixed length circuit including one of input/output pins of the first flip-flop; and
a first variable length circuit including another of the input/output pins of the first flip-flop,
wherein the second flip-flop comprises:
a second fixed length circuit including one of input/output pins of the second flip-flop; and
a second variable length circuit including the other of the input/output pins of the second flip-flop; and
wherein a cell boundary of the multi-bit flip-flop cell layout includes:
a first side extending from the first fixed length circuit in a second direction perpendicular to the first direction;
a second side extending from the second fixed length circuit in the second direction while forming a straight line with the first side;
a third side extending from the first variable length circuit in the second direction; and
a fourth side extending from the second variable length circuit in the second direction while being misaligned with the third side.

12. The semiconductor circuit design system of claim 11, wherein a second length of the second variable length circuit in the first direction is formed to be longer than a first length of the first variable length circuit in the first direction by a predetermined first length.

13. The semiconductor circuit design system of claim 11, wherein the first flip-flop and the second flip-flop are placed directly adjacent to each other while sharing a clock generation circuit.

14. The semiconductor circuit design system of claim 11, wherein the multi-bit flip-flop cell layout further includes:
a third flip-flop formed to extend parallel to the first flip-flop and the second flip-flop along the first direction, wherein the third flip-flop comprises:
a third fixed length circuit including one of input/output pins of the third flip-flop; and
a third variable length circuit including the other of the input/output pins of the third flip-flop, and
wherein a cell boundary of the multi-bit flip-flop cell layout includes:
a fifth side extending from the third fixed length circuit in the second direction while forming a straight line with the first side and the second side, and
a sixth side extending from the third variable length circuit in the second direction while being misaligned with both the third side and the fourth side.

15. The semiconductor circuit design system of claim 14, wherein a third length of the third variable length circuit in the first direction is formed to be longer than a first length of the first variable length circuit in the first direction by a predetermined second length.

16. A processor-implemented method, the method comprising:
executing a layout design tool for a layout design of a semiconductor circuit loaded into a memory device;
accessing a cell library;
selecting a standard cell provided from the cell library;
placing the selected standard cell according to a predetermined design rule; and
performing routing on the placed standard cell,
wherein the standard cell includes a multi-bit flip-flop cell layout,
wherein the multi-bit flip-flop cell layout includes:
a first flip-flop formed to extend along a first direction, and
a second flip-flop formed to extend parallel to the first flip-flop along the first direction;
wherein the first flip-flop comprises:
a first fixed length circuit including one of input/output pins of the first flip-flop; and
a first variable length circuit including another of the input/output pins of the first flip-flop,
wherein the second flip-flop comprises:
a second fixed length circuit including one of input/output pins of the second flip-flop; and
a second variable length circuit including the other of the input/output pins of the second flip-flop, and
wherein a cell boundary of the multi-bit flip-flop cell layout includes:
a first side extending from the first fixed length circuit in a second direction perpendicular to the first direction,
a second side extending from the second fixed length circuit in the second direction while forming a straight line with the first side,
a third side extending from the first variable length circuit in the second direction, and
a fourth side extending from the second variable length circuit in the second direction while being misaligned with the third side.

17. The method for designing the semiconductor circuit of claim 16, wherein a second length of the second variable length circuit in the first direction is formed to be longer than a first length of the first variable length circuit in the first direction by a predetermined first length.

18. The method for designing the semiconductor circuit of claim 16, further comprising:
placing the first flip-flop and the second flip-flop adjacent to each,
wherein the first flip-flop and the second flip-flop share a clock generation circuit.

19. The method for designing the semiconductor circuit of claim 16, wherein the multi-bit flip-flop cell layout further comprises:
a third flip-flop configured to extend parallel to the first flip-flop and the second flip-flop along the first direction; and
wherein the third flip-flop comprises:
a third fixed length circuit including one of input/output pins of the third flip-flop; and
a third variable length circuit including the other of the input/output pins of the third flip-flop, and
wherein a cell boundary of the multi-bit flip-flop cell layout includes:
a fifth side extending from the third fixed length circuit in the second direction while forming a straight line with the first side and the second side, and
a sixth side extending from the third variable length circuit in the second direction while being misaligned with both the third side and the fourth side.

20. The method for designing the semiconductor circuit of claim 19, wherein a third length of the third variable length circuit in the first direction is formed to be longer than a first length of the first variable length circuit in the first direction by a predetermined second length.
